(19) United States
(12) Patent Application Publication
(10) Pub. No.: US 2009/0225618 A1
(43) Pub. Date: Sep. 10, 2009

(54) POWER MANAGEMENT MODULE FOR MEMORY MODULE

(75) Inventors: Tin-Chen Ko, Taipei City (TW); Wei-Yi Chu, Taipei City (TW)

Correspondence Address: J C PATENTS, INC., 4 VENTURE, SUITE 250, IRVINE, CA, 92618, US

(73) Assignee: INVENTEC CORPORATION, Taipei City (TW)

(21) Appl. No.: 12/043,028

(22) Filed: Mar. 5, 2008

(51) Int. Cl. G11C 5/14

(52) U.S. Cl. 365/226

(57) ABSTRACT

A power management module for a memory module is provided. The memory module is coupled to a chipset. The power management module includes a basic input/output system (BIOS), a power regulation module, and a DC-DC converter module. The BIOS is coupled to the chipset, and contains a power consumption data of the memory module. The power regulation module is coupled to the BIOS, and is adapted for outputting a power control signal according to the power consumption data of the memory module. The DC-DC converter module is coupled to the memory module and the power regulation module. The DC-DC converter module includes a plurality of DC-DC converters, and is adapted to determine a quantity of the DC-DC converters for enabling according to the power control signal, so as to provide a suitable power to the memory module.

### BACKGROUND OF THE INVENTION

1. Field of the Invention

The present invention generally relates to a power management module, and more particularly, to a power management module for a memory module.

2. Description of Related Art

Recently, as capacities and clock speeds of memory modules being drastically raised, the memory modules correspondingly consume more and more power. Typically, in order to allow a memory module to achieve its optimal performance, a DC-DC converter module is required to provide sufficient power to the memory module. A conventional DC-DC converter module is discussed in general below.

FIG. 1 is a conventional DC-DC converter module 10 for a memory module. Refereeing to FIG. 1, there is shown a central processing unit (CPU) 12 coupled to a chipset 80. The chipset 80 includes a north bridge chip 81, and a south bridge chip 82. The DC-DC converter 10 is coupled to the north bridge chip 81 of the chipset 80. In order to satisfy the demand of the memory module 10 for a greater power, the DC-DC converter module 20 includes three DC-DC converters 31 through 33, are provided for supplying power to the memory module 1Q. A pulse width modulation (PWM) controller 40 is adapted to generate PWM signals PWM1 through PWM3 respectively provided to the DC-DC converters 31 through 33. Phases of the PWM signals PWM1 through PWM3 are different one from another. The DC-DC converters 31 through 33 then respectively provide power to the memory module 10 according to the PWM signals PW1 through PWM3.

Therefore, when there are nine memory units each having a capacity of 8 GB inserted in memory slots 11 of the memory module 10, the memory module 10 requires a power supply about 82 W. The DC-DC converters 31 through 33 respectively provide power of different phases to the memory module 10 to maintain the memory module 10 to perform with the optimal performance. However, when the memory module 10 has three memory units each having a capacity of 8 GB inserted in memory slots 11 thereof, it requires a power supply only about 28 W only. In this case, if the DC-DC converters 31 through 33 keep providing power of different phases to the memory module 10, power would be unnecessarily wasted.

### SUMMARY OF THE INVENTION

Accordingly, the present invention is directed to a power management module for a memory module, which is adapted for saving power.

The present invention provides a power management module for a memory module. The memory module is coupled to a chipset. The power management module includes a basic input/output system (BIOS), a power regulation module, and a DC-DC converter module. The BIOS is coupled to the chipset, and contains a power consumption data of the memory module. The power regulation module is coupled to the BIOS, and is adapted for outputting a power control signal according to the power consumption data of the memory module. The DC-DC converter module is coupled to the memory module and the power regulation module. The DC-DC converter module includes a plurality of DC-DC converters, and is adapted to determine a quantity of the DC-DC converters for enabling according to the power control signal, so as to provide a suitable power to the memory module.

According to an embodiment of the present invention, the DC-DC converter module further includes a PWM controller, a decoder and a switching module. The PWM controller is coupled to each of the DC-DC converters, for providing a PWM signal thereto. The decoder is coupled to the power regulation module, and is adapted to generate a plurality of switching signals according to the power control signal. The switching module includes a plurality of switches, respectively coupled between output terminals of the DC-DC converters and the memory module, each for determining whether to provide a power to the memory module thereby. According to an aspect of the embodiment, the switches are metal oxide semiconductor field effect transistors (MOSFETs), or bipolar junction transistors (BJTs). According to another aspect of the embodiment, the power regulation module includes a baseboard management controller (BMC) or a complex programmable logic device (CPLD) for generating the power control signal.

According to an embodiment of the present invention, the DC-DC converter module further includes a PWM controller. The PWM controller is coupled to each DC-DC converter, for determining whether to provide a PWM signal to the DC-DC converter according to the power control signal, so as to determine a quantity of DC-DC converters for enabling.

According to an embodiment of the present invention, the power regulation module communicates with the DC-DC converter module via an inter-integrated circuit (I2C) bus. According to an aspect of the embodiment, the BIOS communicates with the memory module via a low pin count (LPC) interface, or a firmware hub (FWH). According to another aspect of the embodiment, the chipset includes a north bridge chip and a south bridge chip. The north bridge chip is coupled to the memory module. The south bridge chip is coupled to the north bridge chip and the BIOS. According to still another aspect of the embodiment, the memory module is a dual in-line memory module (DIMM).

The power management module of the present invention employs the power regulation module, and thus is adapted to acquire a power consumption data of the memory module from the BIOS. The DC-DC converter module determines the quantity of the DC-DC converters for enabling according to the power consumption data of the memory module, and thus providing a suitable power to the memory module, so as to save power consumption.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a conventional DC-DC converter module for a memory module.

FIG. 2 is a schematic diagram illustrating a power management module for a memory module according to a first embodiment of the present invention.

FIG. 3 is an isometric diagram illustrating a power regulation module and a DC-DC converter module according to the first embodiment of the present invention.

FIG. 4 is an isometric diagram illustrating a DC-DC converter and a switching module of the first embodiment of the present invention.

FIG. 5 is a schematic diagram illustrating different PWM signals according to the first embodiment of the present invention.

FIG. 6 is a schematic diagram illustrating a power management module for a memory module according to a second embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

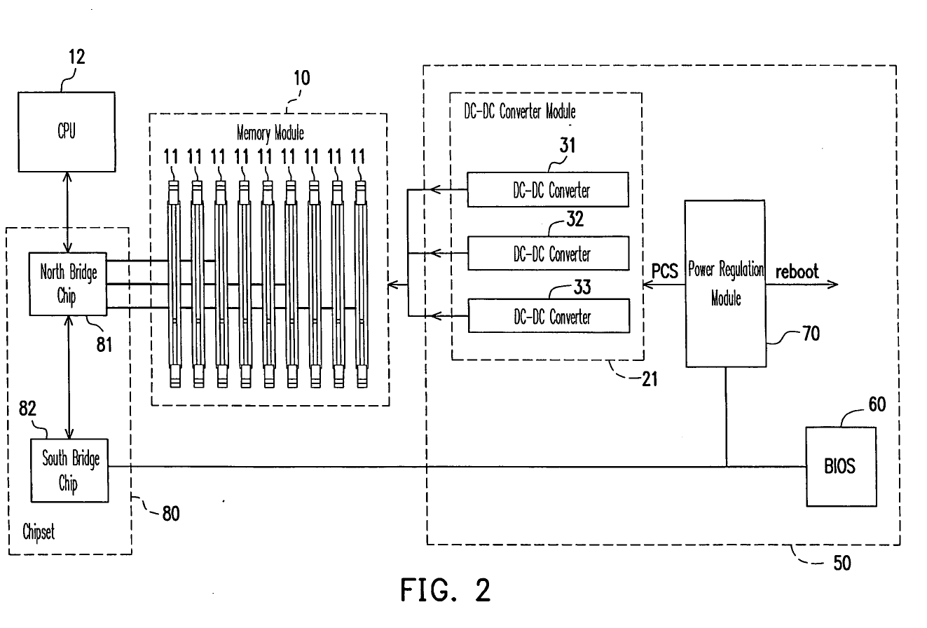

FIG. 2 is a schematic diagram illustrating a power management module for a memory module according a first embodiment of the present invention. Referring to FIG. 2, a chipset 80 including a north bridge chip 81 and a south bridge chip 82, and a power management module 50 for a memory module 10 is provided. The power management module 50 for the memory module 10 includes a BIOS 60, a power regulation module 70, and a DC-DC converter module 21. According to an aspect of the first embodiment, the memory module 10 for example is a dual in-line memory module (DIMM). The memory module 10 is coupled to the north bridge chip 81. The north bridge chip 81 is coupled to a CPU 12 and the south bridge chip 82. The south bridge chip 82 is coupled to the BIOS 60. The BIOS 60 communicates with the south bridge chip via an interface which can be either a low pin count (LPC) interface, or a firmware hub (FWH).

When the memory module 10 is initially installed to a mainboard (not shown), and the computer is booted for the first time, the BIOS 60 acquires and stores data of the memory module 10, e.g., a power consumption data. The power regulation module 70 is coupled to the BIOS 60 and the DC-DC converter module 21, and is adapted to generate a power control signal PCS according to the power consumption data of the memory module 10, and thereby setups the DC-DC converter module 21. The power regulation module 70 communicates with the DC-DC converter module 21 via an interface such as an inter-integrated circuit (I2C) bus. A dynamic adjustment of the power provided by the DC-DC converter module 21 to the memory module 10 often causes a deviation of voltage level, therefore the power regulation module 70 may emit a reboot signal “reboot”, and re-set the DC-DC converter module 21 when rebooting the computer.

The DC-DC converter module 21 is coupled to the memory module 10 and the power regulation module 70. The DC-DC converter module 21 includes a plurality of DC-DC converters. In the current embodiment, it is exemplified with three DC-DC converters 31 through 33 for supplying power to the memory module 10 for illustration. However, it should not be construed as any restriction to the scope of the present invention. As the computer is rebooted, the DC-DC converter module 21 determines a quantity of the DC-DC converters 31 through 33 for enabling, according to the power control signal PCS, so as to supply a suitable power for the memory module 10. In such a way, the DC-DC converter module 21 achieves the object of power saving by supplying suitable power to the memory module according to the quantity and capacity of memory units inserted into slots of the memory module. A process of determining the quantity of the DC-DC converters 31 though 33 is to be illustrated in more details below.

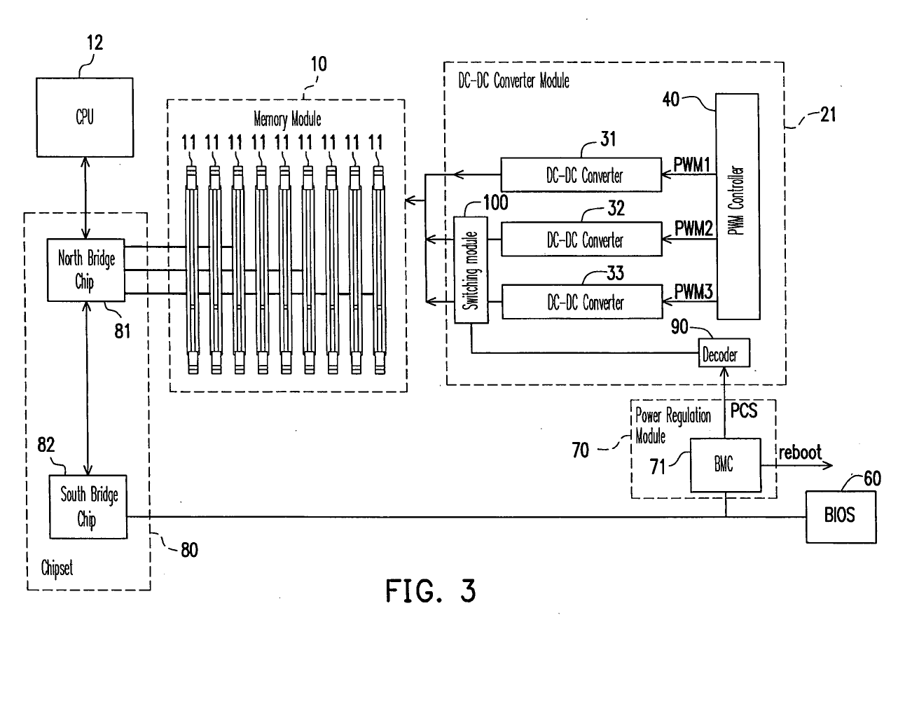

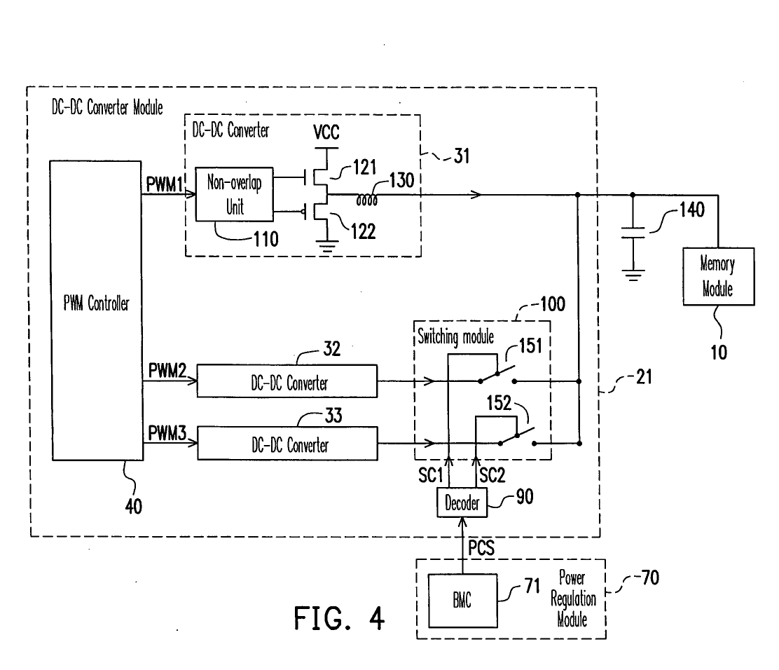

FIG. 3 is an isometric diagram illustrating a power regulation module and a DC-DC converter module according to the first embodiment of the present invention. FIG. 4 is an isometric diagram illustrating a DC-DC converter and a switching module of the first embodiment of the present invention. Referring to FIGS. 2, 3, and 4 together, in the current embodiment, the power regulation module 70 includes a baseboard management controller (BMC) 71 for generating the power control signal PCs.

On the hand, the DC-DC converter module 21 further includes a PWM controller 40, a decoder 90, and a switching module 100. The switching module 100 includes switches 151, and 152. According to an aspect of the embodiment, the switches 151 and 152 are either metal oxide semiconductor field effect transistor (MOSFETs) or bipolar junction transistors (BJTs).

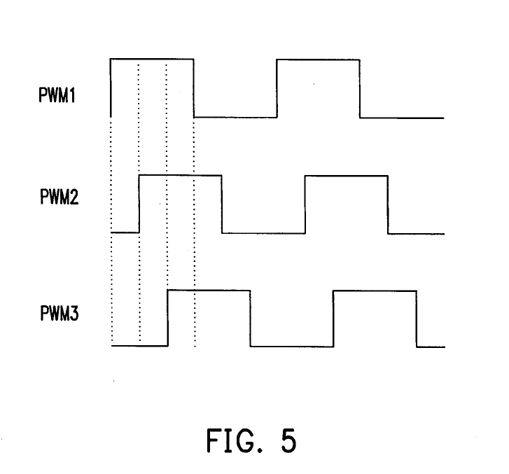

The PWM controller 40 is coupled to the DC-DC converters 31 through 33 for outputting PWM signals PWM1 through PWM3 to the DC-DC converters 31 through 33. The PWM signals PWM1 through PWM4 are different in phase respectively. FIG. 5 is a schematic diagram illustrating different PWM signals according to the first embodiment of the present invention. In the current embodiment, the DC-DC converters 31 through 33 are exemplified as composed of same components, and therefore the structures of the DC-DC converters 31 through 33 are to be illustrated below taking the DC-DC converter 31 as an example.

The DC-DC converter 31 includes a non-overlap unit 110, an upper transistor 121, a lower transistor 122 and an inductor 130. The non-overlap unit 110 is adapted to convert the PWM signal PWM1 into a set of non-overlap signals for controlling the upper transistor 121 and the lower transistor 122 to avoid simultaneous conduction of the upper transistor 121 and the lower transistor 122, which causes a large leakage current. Further, the inductor 130 and a capacitor 140 are adapted to store power in accordance with the operations of the upper transistor 121 and the lower transistor 122, so as to achieve a DC power conversion. The other DC-DC converters 32 through 34 are similar with the DC-DC converter 31 and are not to be iterated hereby.

However, it should be noted that in the current embodiment, the decoder 90 is coupled to the BMC 71, which is adapted to generate switching signals SC1 and SC2 according to the power control signal PCS so as to control the conduction status of the switches 151 and 152. The switches 151 and 152 are respectively coupled between output terminals of the DC-DC converters 32 and 33 and the memory module 10, for determining whether the DC-DC converters 32 and 33 provide power to the memory module 10. In other words, if the memory module 10 has one memory unit having a capacity of 2 GB inserted in the slots, the memory module 10 consumes a power about 14W, and the switches 151 and 152 can be shut off by the switching signals SC1 and SC2, and thus the DC-DC converters 32 and 33 are disabled for avoiding power waste.

Otherwise, if the memory module 10 has two memory units each having a capacity of 8 GB, inserted in the slots, the memory module 10 consumes a power about 28 W, the switch 151 can be turned on and the switch 152 can be shut off by the switching signals SC1 and SC2, and thus the DC-DC converter 33 is disabled for avoiding power waste. Further, if the memory module 10 has nine memory units each having a capacity of 8 GB, inserted in the slots, the memory module 10 consumes a power about 82 W, the switches 151, 152 can be all turned on by the switching signals SC1 and SC2, and thus the DC-DC converters 32 and 33 are both enabled for allowing the memory module 10 to achieve its best performance. In such a way, the memory module 10 can achieve its best performance while saving power when necessary.

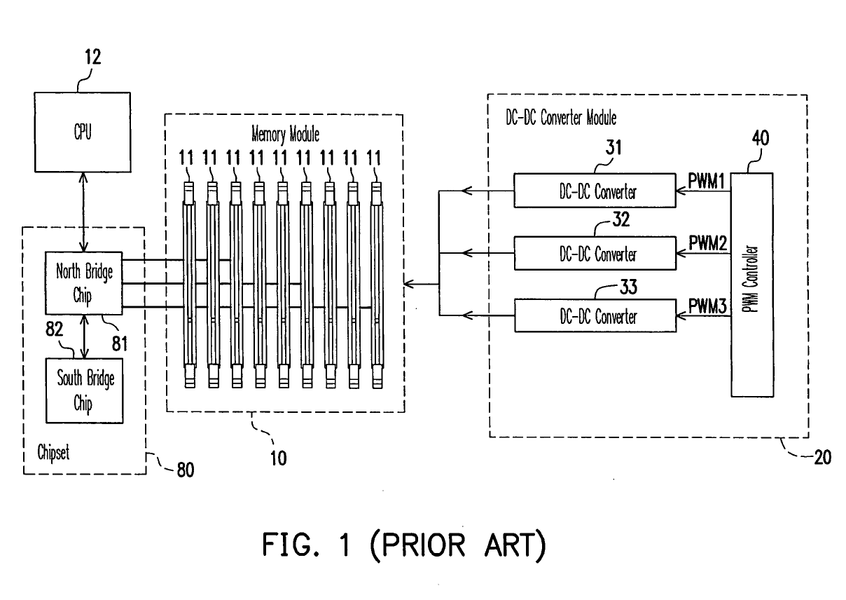

Experiments have been performed for evaluating the performance of power saving according to the embodiment of the present invention. Table 1 is a comparison giving power efficiencies of a conventional memory module and a memory module having the power management module according to the present invention. It can be learnt from the emphasised content in Table 1 that the power efficiency of the embodiment of the present invention is better than the conventional. Referring to FIGS. 1, 2, and table 1, it can be learnt that regardless of how much the memory module 10 consumes, the conventional DC-DC converter module 20 adopts three phases for simultaneously supplying power to the memory module 10 for maintaining the memory module to work with the best performance. However, when the memory module demands only a small power, power will be unnecessarily wasted.

On the contrary, when the memory module 10 consume a power of 14 W, the power management module according to the embodiment of the present invention disables the DC-DC converters 32, 33, and therefore only one DC-DC converter is enabled. The power efficiency of the memory module 10 is enhanced thereby. When the memory module 10 consume a power of about 18 to 42 W, the power management module according to the embodiment of the present invention temporarily disables the DC-DC converter 33, and therefore there are two DC-DC converters are enabled. The power efficiency of the memory module 10 is enhanced thereby.

TABLE 1
Comparison of power efficiencies of a memory module having a present
invented power management module with a conventional memory module

| | | | Power | | | |
|---|---|---|---|---|---|---|
| | | | Efficiency | | | Power |
| | Power | Quantity of | of memory | Power | | Efficiency |
| | Consumption | DC-DC | module | Consumption | | of memory |
| | Data of | Converters | under an | of memory | | module |
| | memory | For | Operation | module under | | under an |
| | module | Enabling | Mode | an Idle Mode | | Idle Mode |
| Conventional | 82 W | 3 | 85% | 24 | W | 83% |
| | 68 W | 3 | 87% | 16 | W | 73% |
| | 42 W | 3 | 85% | 8 | W | 65% |
| | 28 W | 3 | 84% | 5.34 | W | 60% |
| | 21 W | 3 | 82% | 5 | W | 55% |
| | 18 W | 3 | 80% | 4 | W | 51% |
| | 14 W | 3 | 72% | 3.34 | W | 46% |
| Current | 68 W | 2 | 85% | 16 | W | 82% |
| Embodiment | 42 W | 2 | 86% | 8 | W | 75% |
| | 28 W | 2 | 86% | 5.34 | W | 72% |
| | 21 W | 2 | 84% | 5 | W | 65% |
| | 18 W | 2 | 83% | 4 | W | 62% |
| | 14 W | 2 | 73% | 3.34 | W | 52% |
| | 28 W | 1 | 79% | 5.34 | W | 73% |
| | 21 W | 1 | 79% | 5 | W | 72% |
| | 18 W | 1 | 78% | 4 | W | 66% |
| | 14 W | 1 | 77% | 3.34 | W | 63% |

It should be noted that although a preferred embodiment of the power management module for a memory module according to the present invention has been illustrated above, those skilled in the art should be aware of that different manufacturers made different designs about power management modules for memory modules. As such, the application of the present invention should not be restricted as what is disclosed above in the first embodiment. If only a power management module for memory module is featured in that a quantity of DC-DC converters for enabling is determined according to a power consumption data of the memory module, the power management module is within the scope of the present invention.

### Second Embodiment

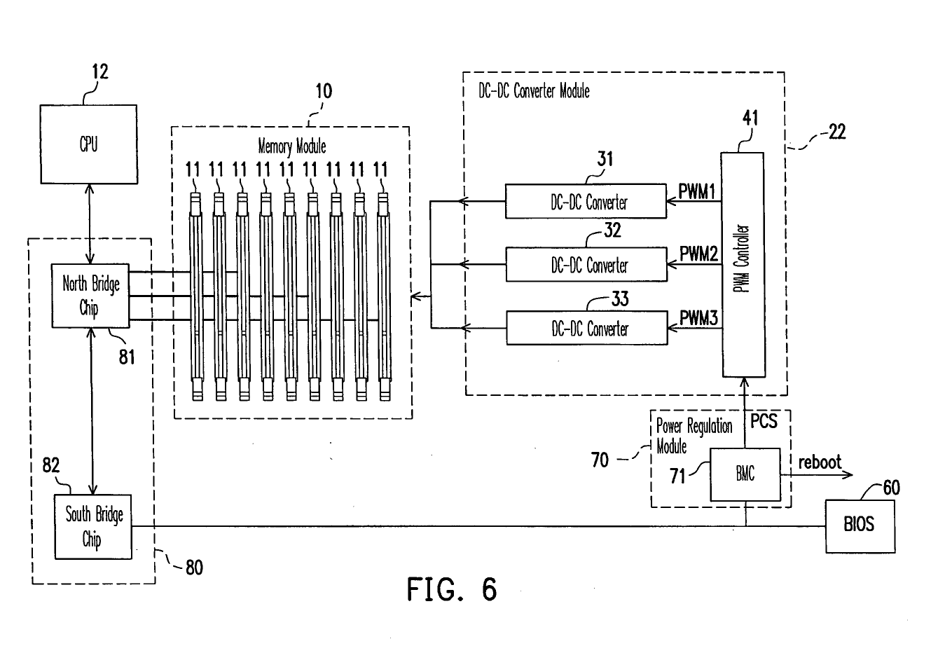

FIG. 6 is a schematic diagram illustrating a power management module for a memory module according a second embodiment of the present invention. In the second embodiment, the same reference numbers are used in the drawings and the description to refer to the same or like parts as exhibited in the first embodiment. Referring to FIGS. 3 and 6 together, there is shown a PWM controller 41 of the DC-DC converter 22 for determining whether to output the PWM signals PWM1 through PWM3 respectively according to the power control signal PCS provided by the BMC 71, so as to determine the quantity of DC-DC converters for enabling.

In more detail, when the memory module 10 consumes a power of 14 W, the PWM controller 41 may suspend the output of the PWM signals PWM2 and PWM3, and therefore there is only one DC-DC converter enabled. When the memory module 10 consumes a power about 18 to 42 W, the PWM controller 41 may suspend the output of the PWM signal PWM3, and therefore there are two DC-DC converters enabled. In such a way, the second embodiment can similarly achieve a same performance as that of the first embodiment, while even saving the hardware cost of the decoder 90 and the switching module 100 as shown in FIG. 3.

Referring to FIGS. 3 and 6, as illustrated in the first and the second embodiments, a BMC 71 is employed by the power regulation module 70 for generating the power control signal PCS. While according to another aspect of the above embodiments, a complex programmable logic device (CPLD) is alternatively employed by the power regulation module 70 for generating the power control signal PCS.

In summary, the power management module according to the present invention is adapted for determining a quantity of DC-DC converters for enabling according to a power consumption data of a memory module for supplying suitable power to the memory module, and therefore is capable of not only maintaining the calculation capability of the memory module, but also saving power.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A power management module, for a memory module coupled to a chipset, comprising:
a basic input/output system (BIOS) chip, coupled to the chipset, and having a power consumption data of the memory module;
a power regulation module, coupled to the BIOS, and adapted for outputting a power control signal according to the power consumption data of the memory module; and
a DC-DC converter module, coupled to the memory module and the power regulation module, the DC-DC converter module having a plurality of DC-DC converters, and being adapted to determine a quantity of the DC-DC converters for enabling according to the power control signal, so as to provide a suitable power to the memory module.

2. The power management module according to claim 1, wherein the DC-DC converter module comprises:
a pulse width modulation (PWM) controller, coupled to each of the DC-DC converters for providing a PWM signal thereto;
a decoder, coupled to the power regulation module, and used to generate a plurality of switching signals according to the power control signal; and
a switching module, having a plurality of switches respectively coupled between output terminals of the DC-DC converters and the memory module, each for determining whether to provide a power to the memory module.

3. The power management module according to claim 2, wherein the switches are metal oxide semiconductor field effect transistors (MOSFETs), or bipolar junction transistors (BJTs).

4. The power management module according to claim 2, wherein the power regulation module comprises a baseboard management controller (BMC) coupled to the PWM controller for generating a power control signal.

5. The power management module according to claim 2, wherein the power regulation module comprises a complex programmable logic device (CPLD) coupled to the PWM controller for generating a power control signal.

6. The power management module according to claim 1, wherein the DC-DC converter module further comprises:
a PWM controller, coupled to each DC-DC converter, for determining whether or not to provide a PWM signal to the DC-DC converter according to the power control signal, so as to determine a quantity of the DC-DC converters for enabling.

7. The power management module according to claim 6, wherein the power regulation module comprises a BMC coupled to the PWM controller for generating a power control signal.

8. The power management module according to claim 6, wherein the power regulation module comprises a CPLD coupled to the PWM controller for generating a power control signal.

9. The power management module according to claim 1, wherein the power regulation module communicates with the DC-DC converter module via an inter-integrated circuit (I2C) bus.

10. The power management module according to claim 1, wherein the BIOS communicates with the chipset via a low pin count (LPC) interface.

11. The power management module according to claim 1, wherein the BIOS communicates with the chipset via a firmware hub (FWH).

12. The power management module according to claim 1, wherein the chipset comprises:
a north bridge chip, coupled to the memory module; and
a south bridge chip, coupled to the north bridge chip and the BIOS.

13. The power management module according to claim 1, wherein the memory module is a dual in-line memory module (DIMM).
